(19) United States
(12) Patent Application Publication
(10) Pub. No.: US 2026/0173839 A1
(43) Pub. Date: Jun. 18, 2026

(54) DUMMY STACKED VIAS TO MITIGATE THERMAL RISK IN BACKSIDE POWER DELIVERY NETWORK

(71) Applicant: QUALCOMM Incorporated, San Diego, CA (US)

(72) Inventors: John Jianhong ZHU, San Diego, CA (US); Junjing BAO, San Diego, CA (US); Abhishek JAIN, San Diego, CA (US); Giridhar NALLAPATI, San Diego, CA (US)

(21) Appl. No.: 18/979,395

(22) Filed: Dec. 12, 2024

(51) Int. Cl. H01L 23/48; H01L 21/768; H01L 23/528

(52) U.S. Cl. CPC H10W 20/20; H10W 20/023; H10W 20/43

(57) ABSTRACT

A three-dimensional (3D) stacked chip is described. The 3D stacked chip includes a carrier substrate. The 3D stacked chip also includes a die having a back-end-of-line (BEOL) layer bonded to the carrier substrate through a bonding layer and an active layer coupled between the BEOL layer and a redistribution layer (RDL). The 3D stacked chip further includes dummy stacked vias extending through the BEOL layer, between the active layer and the carrier substrate.

### BACKGROUND

### Field

Aspects of the present disclosure relate to integrated circuits (ICs) and, more particularly, to dummy stacked vias for mitigating thermal risk in a backside power delivery network (BSPDN).

### BACKGROUND

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has increased due to the substantial number of devices that are now interconnected in a modern electronic device. The increased number of interconnect levels for supporting the increased number of devices involves more intricate processes.

State-of-the-art mobile application devices demand a small form factor, low cost, a tight power budget, and high electrical performance. Mobile package design has evolved to meet these divergent goals for enabling mobile applications that support multimedia enhancements. These mobile applications, however, are susceptible to power routing issues when multiple dies are stacked in the small form factor.

### SUMMARY

A three-dimensional (3D) stacked chip is described. The 3D stacked chip includes a carrier substrate. The 3D stacked chip also includes a die having a back-end-of-line (BEOL) layer bonded to the carrier substrate through a bonding layer and an active layer coupled between the BEOL layer and a redistribution layer (RDL). The 3D stacked chip further includes dummy stacked vias extending through the BEOL layer, between the active layer and the carrier substrate.

A method for forming a three-dimensional (3D) stacked chip is described. The method includes forming a plurality of dummy stacked vias extending through back-end-of-line (BEOL) layers. The method also includes bonding a carrier substrate to the BEOL layers. The method further includes coupling a frontside of an active layer of a die to the BEOL layers, distal from the carrier substrate. The method also includes forming a backside power delivery network (BSPDN) on a backside of the active layer of the die.

This has outlined, broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for conducting the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-a-chip (SOC), including dummy stacked vias for mitigating thermal risk in a backside power delivery network (BSPDN), in accordance with certain aspects of the present disclosure.

FIG. 2 shows a cross-sectional view of a stacked integrated circuit (IC) package of the host system-on-a-chip (SOC) of FIG. 1.

FIG. 3 shows a cross-sectional view illustrating the stacked integrated circuit (IC) package of FIG. 2, incorporated into a wireless device, according to one aspect of the present disclosure.

FIGS. 4A and 4B are block diagrams illustrating cross-sectional views of a three-dimensional (3D) stacked chip having dummy stacked vias for mitigating thermal risk in a backside power delivery network (BSPDN), according to various aspects of the present disclosure.

FIGS. 5A and 5B illustrate dummy stacked vias formed in thermal hot spot regions of a three-dimensional (3D) stacked chip, according to various aspects of the present disclosure.

FIGS. 6A-6C are block diagrams illustrating dummy stacked via configurations, according to various aspects of the present disclosure.

FIGS. 7A-7F are cross-sectional diagrams illustrating a process for fabricating the three-dimensional (3D) stacked chip having dummy stacked vias for mitigating thermal risk in a backside power delivery network (BSPDN) of FIG. 4B, according to various aspects of the present disclosure.

FIG. 8 is a process flow diagram illustrating a method for forming a three-dimensional (3D) stacked chip having dummy stacked vias for mitigating thermal risk in a backside power delivery network (BSPDN), according to various aspects of the present disclosure.

FIG. 9 is a block diagram showing an exemplary wireless communications system, in which an aspect of the present disclosure may be advantageously employed.

FIG. 10 is a block diagram illustrating a design workstation used for circuit, layout, and logic design of a semiconductor component such as the three-dimensional (3D) stacked chip disclosed herein.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

A system hierarchy includes interconnection of active devices at a lowest system level all the way up to system level interconnections at a highest level. Electrical connections exist at each of the levels of the system hierarchy to connect different devices together on an integrated circuit (IC). As integrated circuits become more complex, however, more interconnect layers are used to provide the electrical connections between the devices. More recently, the number of interconnect levels for circuitry has increased due to the substantial number of devices that are now interconnected in a state-of-the-art mobile application device.

These interconnections include back-end-of-line (BEOL) layers, which may refer to the conductive interconnect layers for electrically coupling to front-end-of-line (FEOL) active devices of an integrated circuit (IC). The various BEOL interconnect layers are formed at corresponding BEOL interconnect levels, in which lower BEOL interconnect levels use thinner metal layers relative to upper BEOL interconnect levels. The BEOL interconnect layers may electrically couple to middle-of-line (MOL) interconnect layers, which interconnect to the FEOL active devices of an IC.

State-of-the-art mobile application devices demand a small form factor, low cost, a tight power budget, and high electrical performance. Mobile package design has evolved to meet these divergent goals for enabling mobile applications that support multimedia enhancements. Stacked die schemes and chiplet architectures are becoming mainstream as significant power performance area (PPA) yield enhancements are demonstrated for stacked die and chiplet architecture product lines. Unfortunately, successful stacked die schemes involve high power density targets, which impose significant power distribution losses.

Additionally, these mobile applications are susceptible to power routing issues when multiple dies are stacked in the small form factor. Unfortunately, power density for an IC utilized by these mobile applications is continually increasing, and the design of a power delivery network and heat dissipation is now a key bottleneck for the future advancement of IC design. Additionally, this problem is even more challenging when implementing a three-dimensional (3D) stacked chip architecture that is specified to extend Moore's law.

Various aspects of the present disclosure provide dummy stacked vias for mitigating thermal risk in a backside power delivery network (BSPDN). The process flow for fabrication of the dummy stacked vias in a 3D chip stacking may further include formation of a BSPDN for the 3D chip stack. It will be understood that the term “layer” includes film and is not construed as indicating a vertical or horizontal thickness unless otherwise stated. As described, the term “substrate” may refer to a substrate of a diced wafer or may refer to a substrate of a wafer that is not diced. As further described, the term “laminate” may refer to a multilayer sheet to enable packaging of an IC device. As described, the term “chiplet” may refer to an integrated circuit block, a functional circuit block, or other like circuit block specifically designed to work with other similar chiplets to form a larger, more complex chiplet architecture. The terms “substrate,” “wafer,” and “laminate” may be used interchangeably. Similarly, the terms “chip,” “chiplet,” and “die” may be used interchangeably.

Aspects of the present disclosure are directed to dummy stacked vias. In some aspects of the present disclosure, a three-dimensional (3D) stacked chip includes a carrier substrate. Additionally, the 3D stacked chip includes a die having a back-end-of-line (BEOL) layer. In some implementations, the BEOL layer is bonded to the carrier substrate through a bonding layer. Additionally, the BEOL layer is coupled to a frontside of an active layer and a redistribution layer (RDL) is coupled to a backside of the active layer. In various aspects of the present disclosure, the 3D stacked chip includes dummy stacked vias extending through the BEOL layer, between the active layer and the carrier substrate.

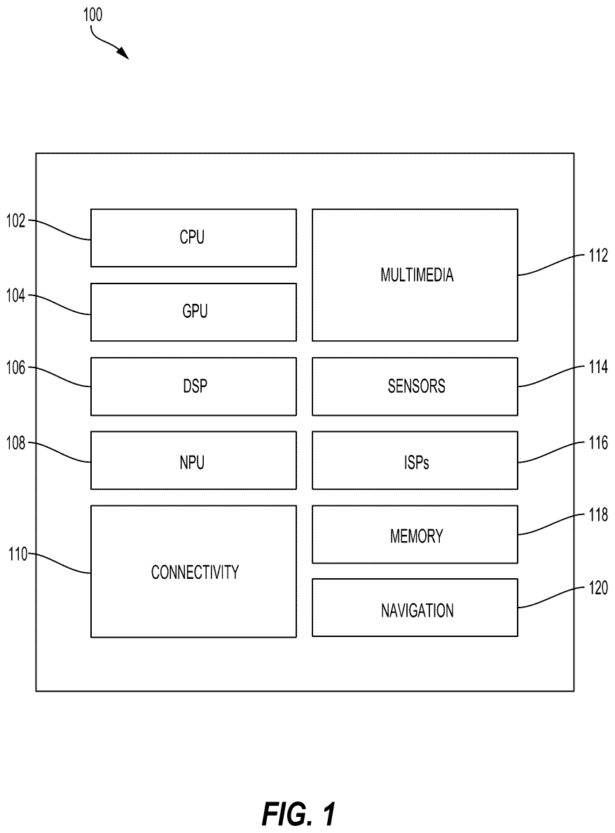

FIG. 1 illustrates an example implementation of a host system-on-a-chip (SOC) 100, which includes dummy stacked vias for mitigating thermal risk in a backside power delivery network (BSPDN), in accordance with certain aspects of the present disclosure. The host SOC 100 includes processing blocks tailored to specific functions, such as a connectivity block 110. The connectivity block 110 may include sixth generation (6G) connectivity, fifth generation (5G) new radio (NR) connectivity, fourth generation long term evolution (4G LTE) connectivity, Wi-Fi connectivity, USB connectivity, Bluetooth® connectivity, Secure Digital (SD) connectivity, and the like.

In this configuration, the host SOC 100 includes various processing units that support multi-threaded operation. For the configuration shown in FIG. 1, the host SOC 100 includes a multi-core central processing unit (CPU) 102, a graphics processor unit (GPU) 104, a digital signal processor (DSP) 106, and a neural processor unit (NPU) 108. The host SOC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, RISC-V, an advanced RISC machine (ARM), a microprocessor, or any reduced instruction set computing (RISC) architecture. The NPU 108 may be based on an ARM instruction set.

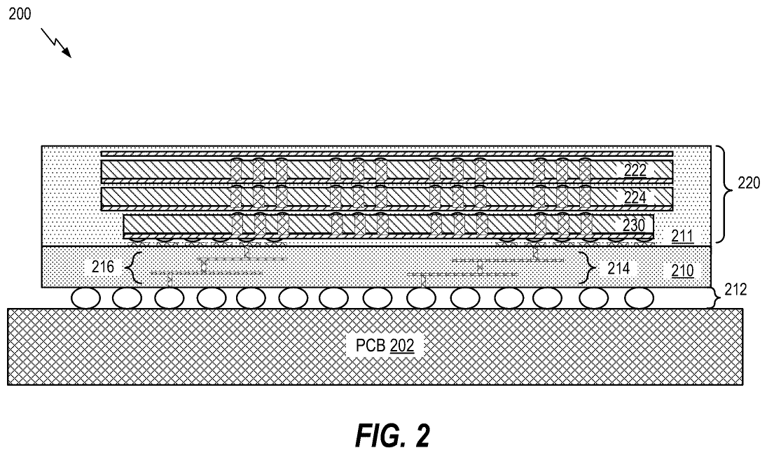

FIG. 2 shows a cross-sectional view of a stacked integrated circuit (IC) package 200 of the host system-on-a-chip (SOC) 100 of FIG. 1. Representatively, the stacked IC package 200 includes a printed circuit board (PCB) 202 connected to a package substrate 210 with interconnects 212. In this configuration, the package substrate 210 includes conductive layers 214 and 216. Above the package substrate 210 is a 3D chip stack 220, including stacked dies 222, 224, and 230, encapsulated by mold compound 211. In one aspect of the present disclosure, the die 230 is the host SOC 100 of FIG. 1.

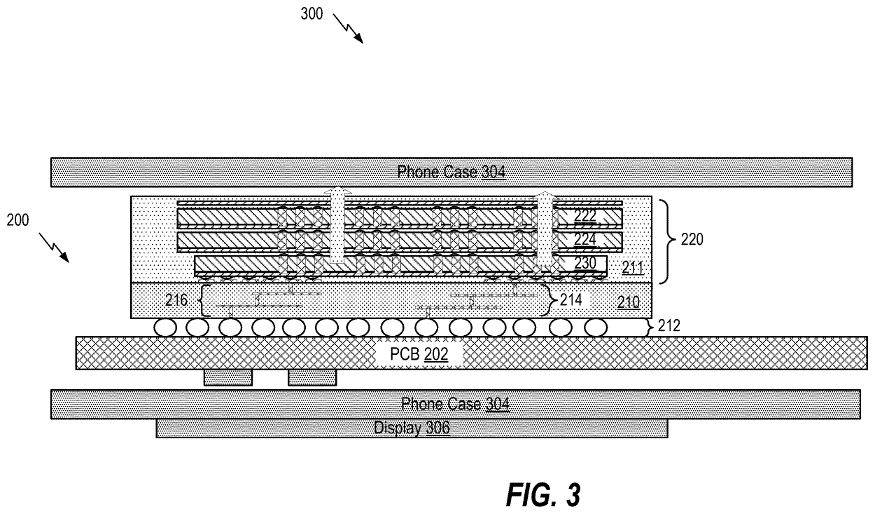

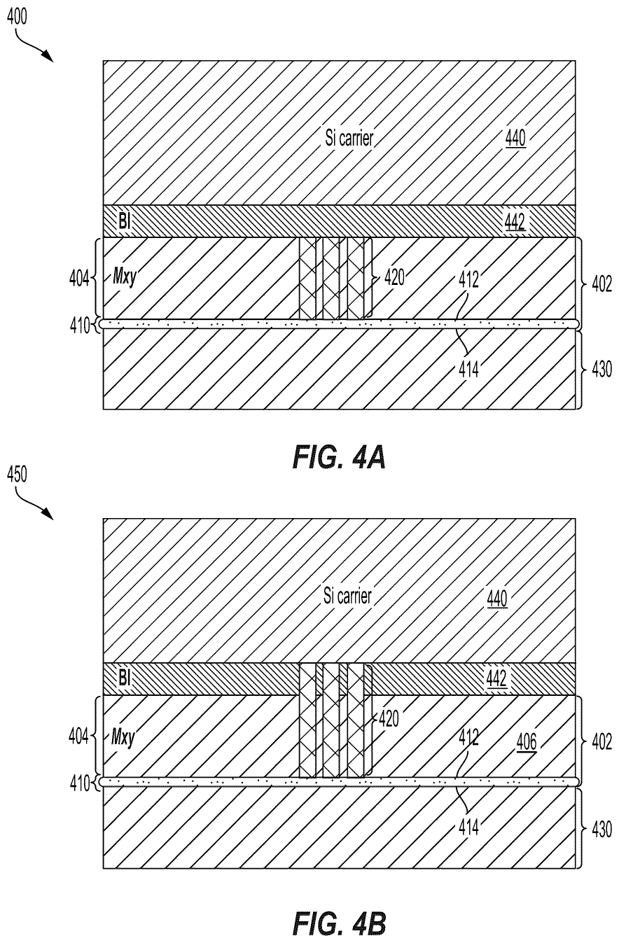

FIG. 3 shows a cross-sectional view illustrating the stacked integrated circuit (IC) package 200 of FIG. 2, incorporated into a wireless device 300, according to one aspect of the present disclosure. As described, the wireless device 300 may include, but is not limited to, a smartphone, tablet, handheld device, or other limited form factor device configured for fifth generation new radio (5G NR)/sixth generation (6G) communications. Representatively, the stacked IC package 200 is within a phone case 304, including a display 306. In this configuration, dummy stacked vias are integrated in the stacked IC package 200 for mitigating thermal risk in a backside power delivery network (BSPDN), for example, as shown in FIGS. 4A to 7E.

FIGS. 4A and 4B are block diagrams illustrating cross-sectional views of a three-dimensional (3D) stacked chip having dummy stacked vias for mitigating thermal risk in a backside power delivery network (BSPDN), according to various aspects of the present disclosure. Aspects of the present disclosure are directed to dummy stacked vias integrated in a 3D stacked chip 400 for mitigating the thermal risk in a BSPDN of the 3D stacked chip 400.

As shown in FIG. 4A, the 3D stacked chip 400 includes a die 402 having a back-end-of-line (BEOL) layer 404 (e.g., multiple BEOL copper (Cu) layers) surrounded by a dielectric layer 408 (e.g., an interlayer dielectric (ILD)) on a frontside 412 of an active layer 410 of the die 402 and coupled to active devices of the active layer 410. In some implementations, the BEOL layer 404 is bonded to a carrier substrate 440 through a bonding layer 442 (e.g., silicon oxide (SiO₂)). Additionally, the BEOL layer 404 is coupled to the frontside 412 of the active layer 410, and a redistribution layer (RDL) 430 (e.g., multiple RDL copper (Cu) layers) is coupled to a backside 414 of the active layer 410.

According to various aspects of the present disclosure, the RDL 430 includes a BSPDN for powering the active devices of the active layer 410 of the die 402. In this implementation, a heating layer generated by the active layer 410 is separated from the carrier substrate 440 by the BEOL layer 404. Due to low thermal conductivity (e.g., <5 W/m-K) of the BEOL layer 404 relative to a thermal conductivity of silicon (e.g., ˜150 W/m-K), a maximum thermal junction temperature (Tjmax) of the die 402 increases. For example, thermal simulation indicates that relying on the separation provided by the BEOL layer 404 can cause a substantial increase (e.g., ˜20 degrees C.(20° C.)) of the Tjmax of the die 402.

In various aspects of the present disclosure, the 3D stacked chip 400 includes dummy whole through dielectric vias 420, extending through the dielectric layer 408 of the BEOL layer 404, between the active layer 410 and the bonding layer 442 of the carrier substrate 440. As shown in FIG. 4A, the 3D stacked chip 400 includes the dummy whole through dielectric vias 420, which operate as thermal vias for reducing a thermal junction temperature (Tj). This implementation relies on the increased thermal conductivity of the carrier substrate 440 (e.g., silicon (Si)) for cooling hot spots of the die 402 to mitigate thermal risk in the BSPDN.

As shown in FIG. 4B, a 3D stacked chip 450 extends the dummy whole through dielectric vias 420 of the 3D stacked chip 400 of FIG. 4A, according to various aspects of the present disclosure. Accordingly, the 3D stacked chip 450 of FIG. 4B is similar to the implementation of the 3D stacked chip 400 of FIG. 4A and described using similar reference numbers. In this implementation, the dummy whole through dielectric vias 420 extend through the bonding layer 442 to provide improved thermal mitigation by further reducing the thermal junction temperature Tj of the 3D stacked chip 450.

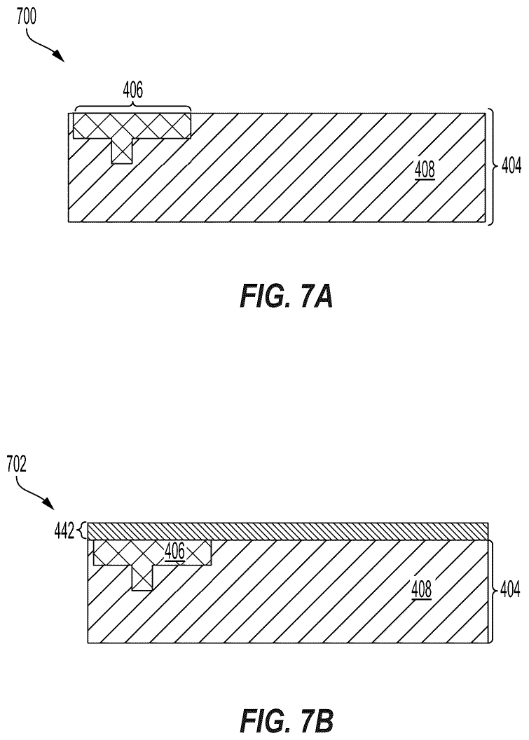

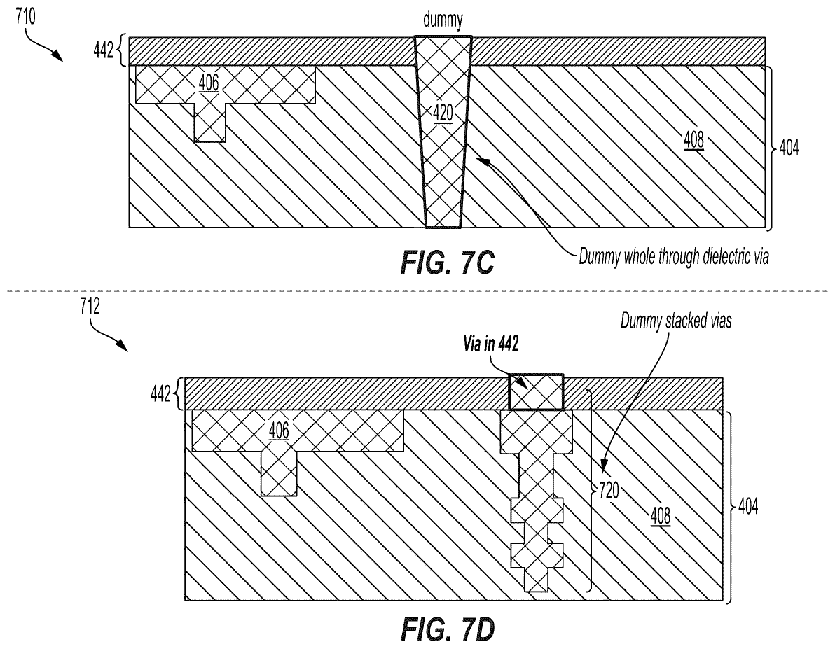

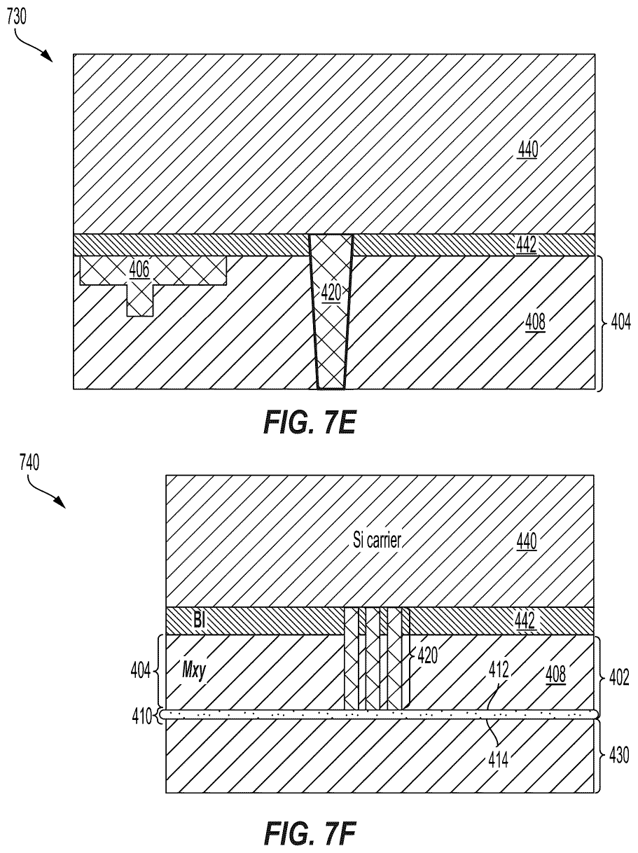

In this implementation, the dummy whole through dielectric vias 420 are formed as whole through dielectric via that are post processed through a via-last process, for example, as shown in FIGS. 7A-7C and 7E-7F. In some implementations, the dummy whole through dielectric vias 420 are replaced with dummy stacked vias 720, for example, as shown in FIG. 7D. In FIGS. 4A and 4B, the dummy whole through dielectric vias 420 are shown as floating vias, which are not electrically contacted to active circuits of a die 402. In this example, the dummy whole through dielectric vias 420 do not extend through the bonding layer 442 (FIG. 4A) or the carrier substrate 440 (FIG. 4B). Additionally, the dummy whole through dielectric vias 420 have a uniform size through dielectric layer 408 of the BEOL layer 404 rather than a non-uniform size of the dummy stacked vias 720, as shown in FIG. 7D.

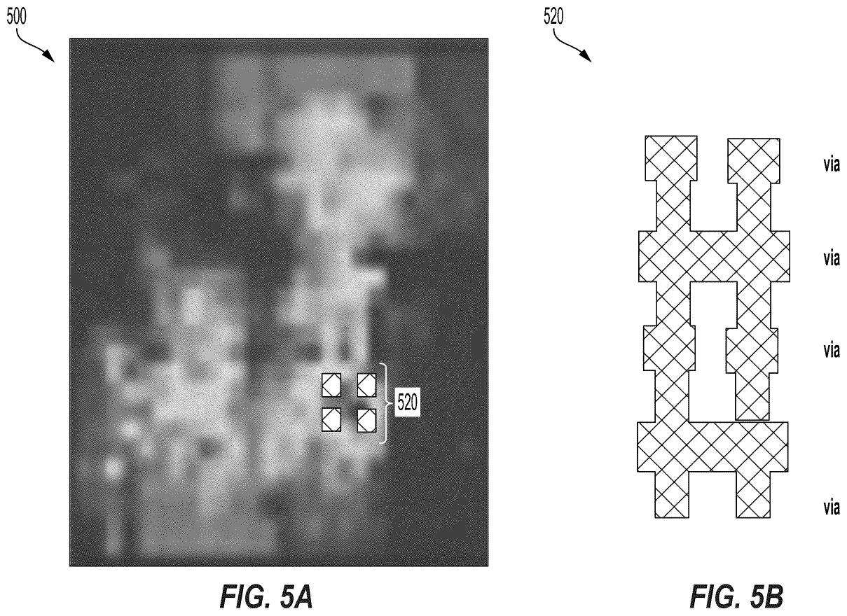

FIGS. 5A and 5B illustrate dummy stacked vias formed in thermal hot spot regions in a three-dimensional (3D) stacked chip, according to various aspects of the present disclosure. FIG. 5A illustrates a top view of thermal hotspot regions of a back-end-of-line (BEOL) layer 500.

Aspects of the present disclosure recognize a technology trend, which specifies implementation of a backside power delivery network (BSPDN) in advanced tech nodes. Unfortunately, implementation of a BSPDN increases a thermal risk because the separation of the heating layer of a die from a carrier substrate is limited to the BEOL layer 500. As shown in FIG. 5A, dummy stacked vias 520 are implemented in thermal hot spot regions of the BEOL layer 500 to mitigate thermal risk in a BSPDN by lowering the maximum thermal junction temperature (Tjmax). Various aspects of the present disclosure form the dummy stacked vias 520 to extend through an entirety of the BEOL layer 500 (instead of being limited to the lower metal levels of the BEOL layer 500).

As shown in FIG. 5A, the dummy stacked vias 520 are introduced in selected areas (e.g., thermal hot spots in central processing unit (CPU) regions) to mitigate a thermal risk without involving additional processes. Utilizing the dummy stacked vias 520 beneficially lowers a hot spot temperature (e.g., >4° C.) without involving additional processes. Additionally, utilization of the dummy stacked vias 520 exhibits a negligible impact on chip package integration (CPI) because implementation of the dummy stacked vias 520 is limited to the thermal hot spot regions of the BEOL layer 500.

As shown in FIG. 5B, the dummy stacked vias 520 are formed utilizing a high (e.g., 5-10%) via density; however, a via cluster size of the dummy stacked vias 520 depends on thermal hot spot size of the BEOL layer 500. For example, the via sizes of the dummy stacked vias 520 are selected to comply with design rules (DRs) or with a dedicated design rule (e.g., a large via critical dimension (CD) is desired). In some implementations, the dummy stacked vias 520 are formed through a via-last process, such as a through dielectric vias, for example, as shown in FIG. 7A-7C.

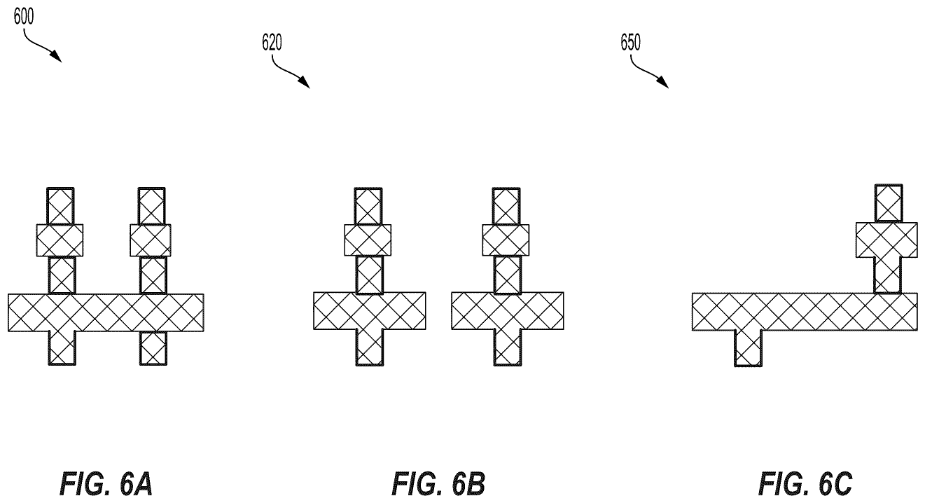

FIGS. 6A-6C are block diagrams illustrating dummy stacked via configurations, according to various aspects of the present disclosure. FIG. 6A further illustrates a portion 600 of the dummy stacked vias 520, as shown in FIG. 5B. FIG. 6B illustrates side-by-side dummy stacked vias 620, which may be formed by separating the portion 600 of the dummy stacked vias 520, as shown in FIG. 6A. FIG. 6C, illustrates dummy stacked vias 650, in which a lateral shift of the dummy stacked vias 650 is provided for allowing track use by a circuit.

A process of fabricating a three-dimensional (3D) stacked chip is shown in FIGS. 7A-7F. FIGS. 7A-7F are cross-sectional diagrams illustrating a process for fabricating the 3D stacked chip 450 of FIG. 4B, having the dummy whole through dielectric vias 420 or dummy stacked vias 720, as shown in FIG. 7D, according to various aspects of the present disclosure.

FIG. 7A illustrates a first step 700 for fabricating the 3D stacked chip 450 of FIG. 4B, having the dummy whole through dielectric vias 420. In various aspects of the present disclosure, a metallization layer 406 (Mx) is formed in the BEOL layer 404 as a topmost copper (Cu) metal layer in a front-side of the BEOL layer 404.

FIG. 7B illustrates a second step 702 for fabricating the 3D stacked chip 450 of FIG. 4B, having the dummy whole through dielectric vias 420, according to various aspects of the present disclosure. The second step 702 illustrates formation of the bonding layer 442 (BL) on the BEOL layer 404. The second step 702 may be performed by depositing a layer of silicon dioxide (SiO₂) on a surface of the BEOL layer 404.

FIG. 7C illustrates a third step 710 for fabricating the 3D stacked chip 450 of FIG. 4B, having the dummy whole through dielectric vias 420, according to various aspects of the present disclosure. The third step 710 illustrates a via-last process to form the dummy whole through dielectric vias 420 through the bonding layer 442 and the BEOL layer 404. Formation of the dummy whole through dielectric vias 420 may include a lithographic step to define the dummy whole through dielectric vias 420 followed by an etch process to form a via opening. A metallization process (e.g., barrier/liner deposition) is followed by a metal plating step to fill the via opening. For example, the metal plating step may involve a copper plating step or other like metal plating step (e.g., tungsten plating). Subsequently, a chemical mechanical polishing (CMP) process completes formation of the dummy whole through dielectric vias 420.

FIG. 7D illustrates an alternate step 712 for fabricating the 3D stacked chip 450 of FIG. 4B, having dummy stacked vias 720, according to various aspects of the present disclosure. The alternate step 712 illustrates a via-last process to form the dummy stacked vias 720 through the bonding layer 442 and the BEOL layer 404. Formation of the dummy stacked vias 720 may include a lithographic step to define an opening through the dielectric layer 408 followed by an etch process to form a via opening. A metallization process (e.g., barrier/liner deposition) is followed by a metal plating step to fill the via opening and form a through dielectric via portion. For example, the metal plating step may involve a copper plating step or other like metal plating step (e.g., tungsten plating). Next, a final via is formed through the bonding layer and landing on the through dielectric via portion to complete formation of the dummy stacked vias 720. Subsequently, a chemical mechanical polishing (CMP) process completes formation of the dummy stacked vias 720.

FIG. 7E illustrates a fourth step 730 for fabricating the 3D stacked chip 450 of FIG. 4B, having the dummy whole through dielectric vias 420, according to various aspects of the present disclosure. The fourth step 730 illustrates bonding of the carrier substrate 440 to the bonding layer 442.

FIG. 7F illustrates a fifth step 740 for fabricating the 3D stacked chip 450 of FIG. 4B, having the dummy whole through dielectric vias 420, according to various aspects of the present disclosure. The fifth step 740 illustrates bonding of the active layer 410, including the RDL 430 to the BEOL layer 404, which completes formation of the 3D stacked chip 450.

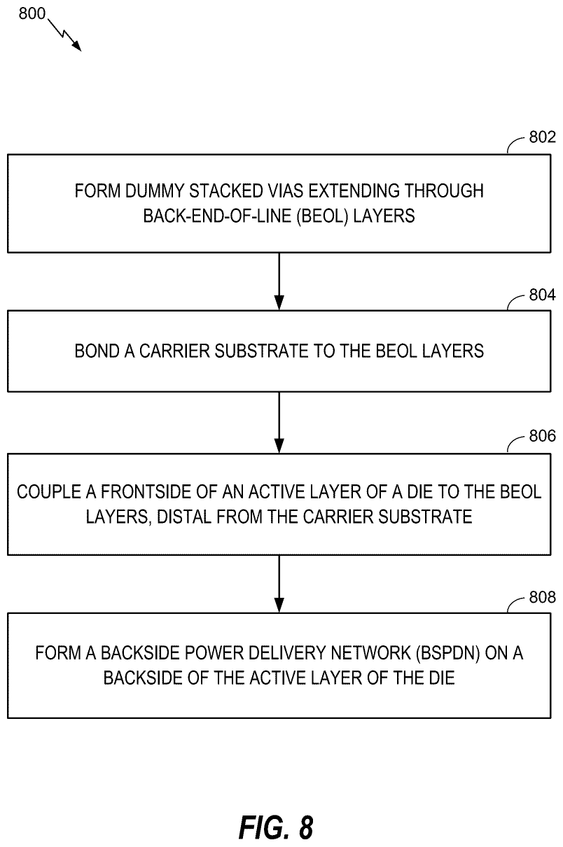

FIG. 8 is a process flow diagram illustrating a method 800 for forming a three-dimensional (3D) stacked chip having dummy stacked vias for mitigating thermal risk in a backside power delivery network (BSPDN), according to various aspects of the present disclosure. The method 800 begins at block 802, in which dummy stacked vias are formed extending through back-end-of-line (BEOL) layers. For example, as shown in FIG. 7C illustrates a via-last process to form the dummy whole through dielectric vias 420 through the bonding layer 442 and the BEOL layer 404. Formation of the dummy whole through dielectric vias 420 may include a lithographic step to define the dummy whole through dielectric vias 420 followed by an etch process to form a via opening. A metallization process (e.g., barrier/liner deposition) is followed by a metal plating step to fill the via opening.

At block 804, a carrier substrate is bond to the BEOL layers. For example, FIG. 7E illustrates a fourth step 730 for fabricating the 3D stacked chip 450 of FIG. 4B, having the dummy whole through dielectric vias 420, according to various aspects of the present disclosure. The fourth step 730 illustrates bonding of the carrier substrate 440 to the bonding layer 442.

At block 806, a frontside of an active layer of a die is couple to the BEOL layers, distal from the carrier substrate. At block 808, a backside power delivery network (BSPDN) is formed on a backside of the active layer of the die. For example, FIG. 7F illustrates a fifth step 740 for fabricating the 3D stacked chip 450 of FIG. 4B, having the dummy whole through dielectric vias 420, according to various aspects of the present disclosure. The fifth step 740 illustrates bonding of the active layer 410, including the RDL 430 to the BEOL layer 404. Additionally, a backside power delivery network (BSPDN) is formed on a backside of the active layer of the die using the RDL 430, which completes formation of the 3D stacked chip 450.

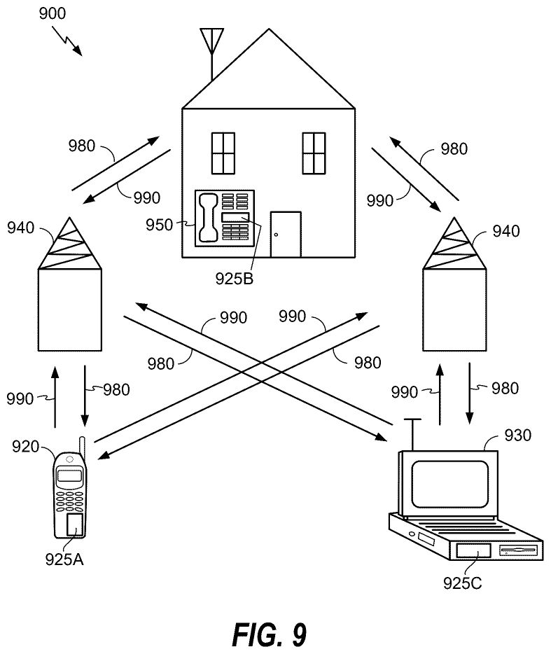

FIG. 9 is a block diagram showing an exemplary wireless communications system 900, in which an aspect of the present disclosure may be advantageously employed. For purposes of illustration, FIG. 9 shows three remote units 920, 930, and 950, and two base stations 940. It will be recognized that wireless communications systems may have many more remote units and base stations. Remote units 920, 930, and 950 include integrated circuit (IC) devices 925A, 925B, and 925C that include the disclosed three-dimensional (3D) stacked chip. It will be recognized that other devices may also include the disclosed 3D stacked chip, such as the base stations, switching devices, and network equipment. FIG. 9 shows forward link signals 980 from the base stations 940 to the remote units 920, 930, and 950, and reverse link signals 990 from the remote units 920, 930, and 950 to the base stations 940.

In FIG. 9, remote unit 920 is shown as a mobile telephone, remote unit 930 is shown as a portable computer, and remote unit 950 is shown as a fixed location remote unit in a wireless local loop system. For example, the remote units may be a mobile phone, a hand-held personal communication systems (PCS) unit, a portable data unit, such as a personal data assistant, a GPS enabled device, a navigation device, a set top box, a music player, a video player, an entertainment unit, a fixed location data unit, such as meter reading equipment, or other device that stores or retrieves data or computer instructions, or combinations thereof. Although FIG. 9 illustrates remote units according to the aspects of the present disclosure, the disclosure is not limited to these exemplary illustrated units. Aspects of the present disclosure may be suitably employed in many devices, which include the disclosed 3D stacked chip.

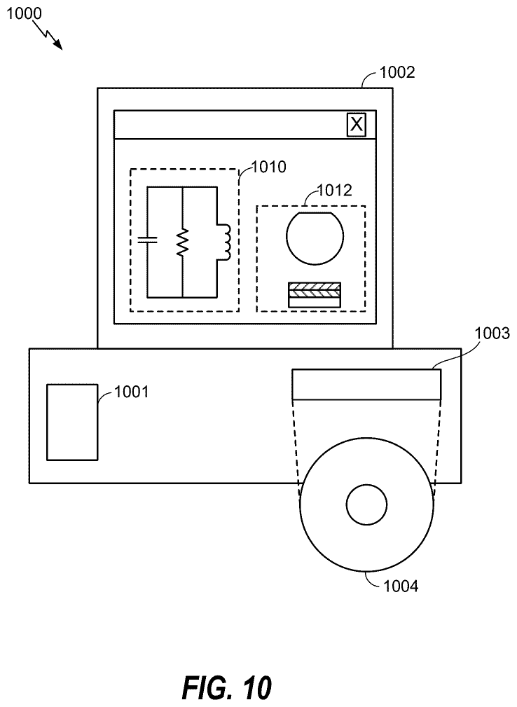

FIG. 10 is a block diagram illustrating a design workstation 1000 used for circuit, layout, and logic design of a semiconductor component, such as the three-dimensional (3D) stacked chip disclosed above. The design workstation 1000 includes a hard disk 1001 containing operating system software, support files, and design software such as Cadence or OrCAD. The design workstation 1000 also includes a display 1002 to facilitate design of a circuit 1010 or a semiconductor component 1012, such as the 3D stacked chip. A storage medium 1004 is provided for tangibly storing the design of the circuit 1010 or the semiconductor component 1012 (e.g., the 3D stacked chip). The design of the circuit 1010 or the semiconductor component 1012 may be stored on the storage medium 1004 in a file format such as GDSII or GERBER. The storage medium 1004 may be a CD-ROM, DVD, hard disk, flash memory, or other appropriate device. Furthermore, the design workstation 1000 includes a drive apparatus 1003 for accepting input from or writing output to the storage medium 1004.

Data recorded on the storage medium 1004 may specify logic circuit configurations, pattern data for photolithography masks, or mask pattern data for serial write tools such as electron beam lithography. The data may further include logic verification data such as timing diagrams or net circuits associated with logic simulations. Providing data on the storage medium 1004 facilitates the design of the circuit 1010 or the semiconductor component 1012 by decreasing the number of processes for designing semiconductor wafers.

Implementation examples are described in the following numbered clauses:
1. A three-dimensional (3D) stacked chip, comprising:
   a carrier substrate;
   a die having a back-end-of-line (BEOL) layer bonded to the carrier substrate through a bonding layer and an active layer coupled between the BEOL layer and a redistribution layer (RDL); and
   a plurality of dummy stacked vias extending through the BEOL layer, between the active layer and the carrier substrate.
2. The 3D stacked chip of clause 1, in which the plurality of dummy stacked vias extend through the bonding layer to contact the carrier substrate.
3. The 3D stacked chip of any of clauses 1 or 2, in which the RDL comprises a backside power delivery network (BSPDN).
4. The 3D stacked chip of any of clauses 1-3, in which the plurality of dummy stacked vias comprises floating vias.
5. The 3D stacked chip of any of clauses 1-4, in which the bonding layer comprises silicon dioxide (SiO₂).
6. The 3D stacked chip of any of clauses 1-5, in which the BEOL layer comprises a metallization layer coupled to active devices of the active layer and surrounded by an interlayer dielectric (ILD).
7. The 3D stacked chip of any of clauses 1-6, in which the plurality of dummy stacked vias are placed according to thermal hot spots of the active layer.
8. The 3D stacked chip of clause 7, in which the plurality of dummy stacked vias are arranged in clusters according to thermal hot spots of the active layer.
9. The 3D stacked chip of any of clauses 1-8, in which the plurality of dummy stacked vias comprise dummy through dielectric vias have a uniform size through an interlayer dielectric layer (ILD) surrounding the BEOL layer.
10. The 3D stacked chip of any of clauses 1-9, in which the plurality of dummy stacked vias have a non-uniform size through an interlayer dielectric layer (ILD) surrounding the BEOL layer.
11. A method for forming a three-dimensional (3D) stacked chip, the method comprising:
   forming a plurality of dummy stacked vias extending through back-end-of-line (BEOL) layers;
   bonding a carrier substrate to the BEOL layers;
   coupling a frontside of an active layer of a die to the BEOL layers, distal from the carrier substrate; and
   forming a backside power delivery network (BSPDN) on a backside of the active layer of the die.
12. The method of clause 11, in which the plurality of dummy stacked vias extend through a bonding layer to contact the carrier substrate.
13. The method of clause 12, in which the bonding layer comprises silicon dioxide (SiO₂).
14. The method of any of clauses 11-11, in which the backside power delivery network (BSPDN) comprises a redistribution layer (RDL).
15. The method of any of clauses 11-14, in which the plurality of dummy stacked vias comprises floating vias.
16. The method of any of clauses 11-15, in which the BEOL layer comprises a metallization layer coupled to active devices of the active layer and surrounded by an interlayer dielectric (ILD).
17. The method of any of clauses 11-16, in which the plurality of dummy stacked vias are placed according to thermal hot spots of the active layer.
18. The method of clause 17, in which the plurality of dummy stacked vias are arranged in clusters according to thermal hot spots of the active layer.
19. The method of any of clauses 11-18, in which the plurality of dummy stacked vias comprise dummy through dielectric vias have a uniform size through an interlayer dielectric layer (ILD) surrounding the BEOL layer.
20. The method of any of clauses 11-19, in which the plurality of dummy stacked vias have a non-uniform size through an interlayer dielectric layer (ILD) surrounding the BEOL layer.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform the same function or achieve the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the application and design constraints imposed on the overall system. Skilled artisans may implement the described functionality in varying ways for each application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described but is to be accorded the widest scope consistent with the principles and novel features disclosed.

What is claimed is:

1. A three-dimensional (3D) stacked chip, comprising:
a carrier substrate;
a die having a back-end-of-line (BEOL) layer bonded to the carrier substrate through a bonding layer and an active layer coupled between the BEOL layer and a redistribution layer (RDL); and
a plurality of dummy stacked vias extending through the BEOL layer, between the active layer and the carrier substrate.

2. The 3D stacked chip of claim 1, in which the plurality of dummy stacked vias extend through the bonding layer to contact the carrier substrate.

3. The 3D stacked chip of claim 1, in which the RDL comprises a backside power delivery network (BSPDN).

4. The 3D stacked chip of claim 1, in which the plurality of dummy stacked vias comprises floating vias.

5. The 3D stacked chip of claim 1, in which the bonding layer comprises silicon dioxide (SiO₂).

6. The 3D stacked chip of claim 1, in which the BEOL layer comprises a metallization layer coupled to active devices of the active layer and surrounded by an interlayer dielectric (ILD).

7. The 3D stacked chip of claim 1, in which the plurality of dummy stacked vias are placed according to thermal hot spots of the active layer.

8. The 3D stacked chip of claim 7, in which the plurality of dummy stacked vias are arranged in clusters according to thermal hot spots of the active layer.

9. The 3D stacked chip of claim 1, in which the plurality of dummy stacked vias comprise dummy through dielectric vias have a uniform size through an interlayer dielectric layer (ILD) surrounding the BEOL layer.

10. The 3D stacked chip of claim 1, in which the plurality of dummy stacked vias have a non-uniform size through an interlayer dielectric layer (ILD) surrounding the BEOL layer.

11. A method for forming a three-dimensional (3D) stacked chip, the method comprising:
forming a plurality of dummy stacked vias extending through back-end-of-line (BEOL) layers;
bonding a carrier substrate to the BEOL layers;
coupling a frontside of an active layer of a die to the BEOL layers, distal from the carrier substrate; and
forming a backside power delivery network (BSPDN) on a backside of the active layer of the die.

12. The method of claim 11, in which the plurality of dummy stacked vias extend through a bonding layer to contact the carrier substrate.

13. The method of claim 12, in which the bonding layer comprises silicon dioxide (SiO₂).

14. The method of claim 11, in which the backside power delivery network (BSPDN) comprises a redistribution layer (RDL).

15. The method of claim 11, in which the plurality of dummy stacked vias comprises floating vias.

16. The method of claim 11, in which the BEOL layer comprises a metallization layer coupled to active devices of the active layer and surrounded by an interlayer dielectric (ILD).

17. The method of claim 11, in which the plurality of dummy stacked vias are placed according to thermal hot spots of the active layer.

18. The method of claim 17, in which the plurality of dummy stacked vias are arranged in clusters according to thermal hot spots of the active layer.

19. The method of claim 11, in which the plurality of dummy stacked vias comprise dummy through dielectric vias have a uniform size through an interlayer dielectric layer (ILD) surrounding the BEOL layer.

20. The method of claim 11, in which the plurality of dummy stacked vias have a non-uniform size through an interlayer dielectric layer (ILD) surrounding the BEOL layer.
